(19) United States
(12) Patent Application Publication
(10) Pub. No.: US 2026/0293698 A1
(43) Pub. Date: Sep. 24, 2026

(54) SUBSTRATE FOR SEMICONDUCTOR DEVICES AND METHOD FOR MANUFACTURING THE SAME

(71) Applicant: HYUNDAI MOBIS CO., LTD., Seoul (KR)

(72) Inventor: Yu Cheol PARK, Yongin-si (KR)

(73) Assignee: HYUNDAI MOBIS CO., LTD., Seoul (KR)

(21) Appl. No.: 19/085,125

(22) Filed: Mar. 20, 2025

(51) Int. Cl. H10W 70/05; H10W 40/22; H10W 70/02; H10W 70/65; H10W 70/66

(52) U.S. Cl. CPC H10W 70/05; H10W 40/22; H10W 70/02; H10W 70/65; H10W 70/66

(57) ABSTRACT

A method for manufacturing a substrate for a semiconductor device for dissipating heat generated from a semiconductor device, and the substrate therefor are provided. The method includes bonding a first bonding layer including a sintered groove at a position corresponding to the semiconductor device on a heat sink, inserting a sintered metal into the sintered groove, bonding a second bonding layer including a circuit board on the first bonding layer, and bonding the semiconductor device on the second bonding layer. At least one of the first bonding layer, the second bonding layer, and the sintered metal include a preform material.

### BACKGROUND

### 1. Field of the Invention

The following disclosure relates to a substrate for a semiconductor device and a method for manufacturing the same, and more particularly, to a substrate for a semiconductor device and a method for manufacturing the same capable of improving heat dissipation performance of a heat sink coupled to a power module.

### 2. Description of the Related Art

A power semiconductor device used in an inverter and the like generates a large amount of heat during operation. Therefore, as a substrate for mounting a power semiconductor device, a substrate for a power module having an insulating substrate made of high heat resistance ceramics, a circuit layer formed on one side of the insulating substrate, and a metal layer formed on the other side of the insulating substrate is used.

In the substrate for the power module, the power semiconductor device is mounted on the circuit layer, a heat sink is brought into contact with a metal layer by interposing a heat conductive material, and heat generated from the power semiconductor device is dissipated to the heat sink.

As the heat conductive material, grease with high heat conductivity has been widely used. When the substrate for the power module and the heat sink are brought into contact with each other through the grease, if the substrate for the power module is warped due to a cooling/heating cycle caused by ON/OFF, etc., of the power semiconductor device, there is a concern that a gap may be generated between the substrate for the power module and the grease and thermal conductivity between the substrate for the power module and the heat sink may deteriorate.

For this reason, a method in which the metal layer of the substrate for the power module and the heat sink are directly bonded using a soldering material is being used. FIG. 1 illustrates a cross-sectional view of a conventional substrate for a power module. A main heat source of a power module 1 is a semiconductor device 10. The semiconductor device 10 is generally soldered to a direct bonded copper (DBC) layer 30 and bonded through a solder layer 20. In this case, in order to dissipate the heat generated from the semiconductor device 10, a thermal interface material (TIM) layer 40 and a heat sink 50 are bonded under the DBC layer 30. The grease is generally used for the TIM layer 40, or a solderable material is used instead of the grease. In addition, as the technology of semiconductor devices is developed more and more, the integration is improved. Accordingly, materials with better thermal conductivity are required, and recently, materials such as silver and copper are sintered and used for the TIM layer 40.

However, the materials such as silver and copper have a problem in that a unit cost of the materials is very high compared to the grease or solderable materials.

### SUMMARY

An embodiment of the present disclosure is directed to improving heat dissipation performance of a semiconductor device while minimizing a unit cost of materials.

In a general aspect of the disclosure, a method for manufacturing a substrate for a semiconductor device for dissipating heat generated from a semiconductor device, includes: (a) bonding a first bonding layer comprising a sintered groove at a position corresponding to the semiconductor device on a heat sink; (b) inserting a sintered metal into the sintered groove; (c) bonding a second bonding layer comprising a circuit board on the first bonding layer; and (d) bonding the semiconductor device on the second bonding layer, wherein at least one of the first bonding layer, the second bonding layer, and the sintered metal comprises a preform material.

The sintered metal may be selected from the group consisting of silver, copper, gold, and aluminum.

At least one of the first bonding layer and the second bonding layer may include a solder material.

The sintered metal may be bonded through a sintering process, wherein the first and second bonding layers may be bonded through a soldering process.

In another general aspect of the disclosure, a method for manufacturing a substrate for a semiconductor device for dissipating heat generated from a semiconductor device, includes: (a) bonding a first bonding layer comprising a sintered groove at a position corresponding to the semiconductor device on a heat sink; (b) bonding a second bonding layer comprising a circuit board under the semiconductor device; (c) bonding a sintered metal at a position corresponding to a position of the semiconductor device under the second bonding layer; and (d) bonding the second bonding layer and the first bonding layer so that the sintered metal is inserted into the sintered groove of the first bonding layer, wherein at least one of the first bonding layer and the sintered metal comprises a paste material.

The sintered metal may be selected from the group consisting of silver, copper, gold, and aluminum.

At least one of the first bonding layer and the second bonding layer may include a solder material.

The sintered metal may be bonded through a sintering process, wherein the first and second bonding layers may be bonded through a soldering process.

In yet another general aspect of the disclosure, a method for manufacturing a substrate for a semiconductor device for dissipating heat generated from a semiconductor device, includes: (a) printing a sintered metal on a heat sink at a position corresponding to the semiconductor device; (b) bonding a first bonding layer comprising a sintered groove into which the sintered metal is inserted on the heat sink so that the sintered metal is inserted into the sintered groove; (c) bonding a second bonding layer comprising a circuit board on the first bonding layer; and (d) bonding the semiconductor device on the second bonding layer, wherein the first bonding layer comprises a preform material, and wherein the sintered metal comprises a paste material.

The sintered metal may be selected from the group consisting of silver, copper, gold, and aluminum.

At least one of the first bonding layer and the second bonding layer may include a solder material.

At least one of the first and second bonding layers may include a material selected from the group consisting of grease, plastic, and ceramic.

The sintered metal may be bonded through a sintering process, wherein the first and second bonding layers may be bonded through a soldering process.

The soldering process may be performed at a higher temperature than the sintering process.

In still another general aspect of the disclosure, a substrate for a semiconductor device for dissipating heat generated from a semiconductor device, includes: a second bonding layer bonded under the semiconductor device to form a circuit board; a first bonding layer bonded under the second bonding layer and having a sintered groove formed at a position corresponding to the semiconductor device; and a heat sink bonded under the first bonding layer, wherein a sintered metal is bonded to the sintered groove of the first bonding layer.

The sintered metal may be selected from the group consisting of silver, copper, gold, and aluminum.

### BRIEF DESCRIPTION OF THE DRAWINGS

FIG. 1 is a cross-sectional view illustrating a conventional substrate for a semiconductor device.

FIG. 2 is a cross-sectional view illustrating a substrate for a semiconductor device according to an embodiment of the present disclosure.

FIGS. 3 to 5 are flowcharts illustrating a method for manufacturing a substrate for a semiconductor device according to an embodiment of the present disclosure.

### DETAILED DESCRIPTION

The above-described objects, features, and advantages of the present disclosure will become more obvious from the following detailed description provided in relation to the accompanying drawings. The following specific structural or functional descriptions are only exemplified for the purpose of describing the embodiments according to the concept of the present disclosure, and the embodiments according to the concept of the present disclosure may be implemented in various forms and should not be construed as limited to the embodiments described herein or in the application. Since embodiments of the concept of the present disclosure may be variously modified and may have several forms, specific embodiments will be illustrated in the accompanying drawings and will be described in detail in the present specification or application. However, it is to be understood that the present disclosure is not limited to specific embodiments, but includes all modifications, equivalents, and substitutions falling in the spirit and the scope of the present disclosure. Terms such as ‘first’, ‘second’, or the like, may be used to describe various components, but these components are not to be construed as being limited to these terms. The terms are used only to distinguish one component from another component. For example, a first component may be named a second component and the second component may also be named the first component, without departing from the scope of the present disclosure. It is to be understood that when one component is referred to as being “connected to” or “coupled to” another component, it may be connected directly to or coupled directly to another component or be connected to or coupled to another component with the other component interposed therebetween. On the other hand, it is to be understood that when one component is referred to as being “connected directly to” or “coupled directly to” another component, it may be connected to or coupled to another component without the other component interposed therebetween. Other expressions for describing the relationship between components, such as between and immediately between or adjacent to and directly adjacent to, etc., should be interpreted similarly. Terms used in the present specification are used only in order to describe specific embodiments rather than limiting the present disclosure. Singular forms include plural forms unless the context clearly indicates otherwise. It is to be understood that terms “include,” “have,” or the like, used in the present specification specify the presence of features, numerals, steps, operations, components, parts, or a combination thereof described in the present specification, but do not preclude the presence or addition of one or more other features, numerals, steps, operations, components, parts, or a combination thereof. Unless indicated otherwise, it is to be understood that all the terms used in the specification including technical and scientific terms have the same meaning as those that are generally understood by those who skilled in the art. Terms generally used and defined in a dictionary are to be interpreted as the same meanings with meanings within the context of the related art, and are not to be interpreted as ideal or excessively formal meanings unless clearly indicated in the present specification. Hereinafter, exemplary embodiments of the present disclosure will be described in detail with reference to the accompanying drawings. The same reference numerals in each drawing denote the same components.

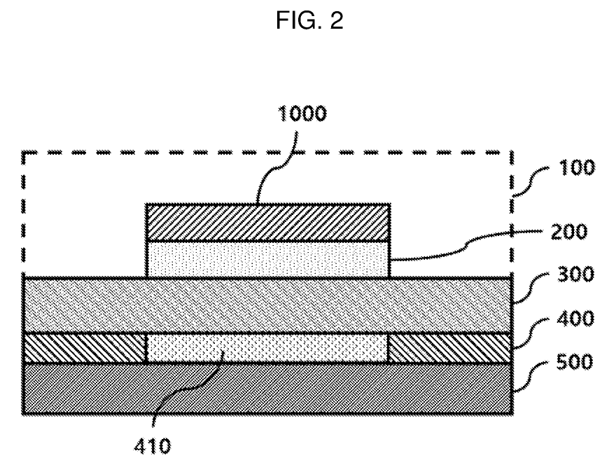

FIG. 2 is a cross-sectional view illustrating a substrate for a semiconductor device according to an embodiment of the present disclosure.

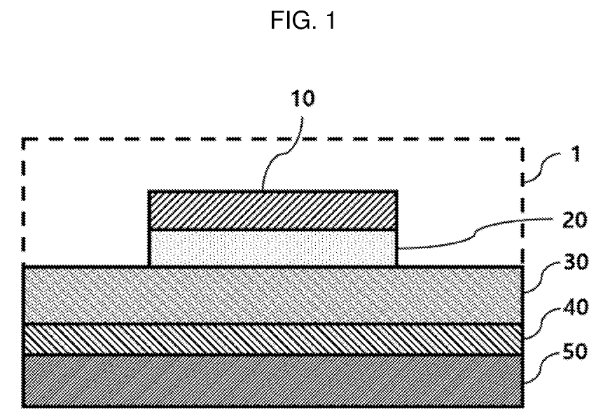

Referring to FIG. 2, the substrate for the semiconductor device according to the present disclosure may include a power module 100, a semiconductor device 1000, a solder layer 200, a second bonding layer 300, a first bonding layer 400, a heat sink 500, and a sintered metal 410. Compared to the conventional substrate for a semiconductor device of FIG. 1, the substrate for the semiconductor device of the present disclosure according to FIG. 2 may include the sintered metal 410 in the first bonding layer 400.

The second bonding layer 300 may be bonded under the semiconductor device 1000 of the power module 100 through the solder layer 200. The second bonding layer 300 electrically connects the power module 100 and may transmit heat generated from the semiconductor device 1000 to the outside when the power module 100 is driven. The second bonding layer 300 may be manufactured mainly by bonding ceramic and copper using a eutectic bonding or active metal brazing (AMB) method. The second bonding layer 300 may be divided into direct bonded copper (DBC), direct bonded aluminum (DBA), etc., depending on the type of metal used. The second bonding layer 300 may be a material including at least one of grease, plastic, and ceramic.

The first bonding layer 400 is bonded under the second bonding layer 300, and a sintered groove is formed at a position corresponding to the semiconductor device 1000, and the sintered metal 410 may be bonded to the sintered groove. The sintered metal 410 may include at least one of silver, copper, gold, and aluminum. The sintered metal 410 may be bonded to the sintered groove formed in the first bonding layer 400 through a sintering process. An area except for the sintered groove where the sintered metal 410 of the first bonding layer 400 is bonded may be bonded through the soldering process. The first bonding layer 400 may be a material including at least one of grease, plastic, and ceramic. In addition, the soldering process of the first bonding layer 400 may be performed at a higher temperature than the sintering process where the sintered metal 410 is bonded.

The heat sink 500 is for cooling the power module 100 and may be bonded under the first bonding layer 400. The inside of the heat sink 500 may be provided with a passage through which a cooling medium circulates to cool the heat generated from the semiconductor device 1000. In addition, instead of forming the passage, the heat sink 500 may be formed in a fin structure on a surface other than a bonding surface of the heat sink 500. The heat sink 500 may be composed of aluminum, aluminum alloy, copper, or copper alloy. The surface of the bonding surface of the heat sink 500 may be formed with a silver plating layer or a gold plating layer. By forming the silver plating layer or the gold plating layer on the heat sink 500, the bonding force between the heat sink 500 and the first bonding layer 400 is strengthened, and the reliability of the power module 100 to which the heat sink 500 is attached may be further improved.

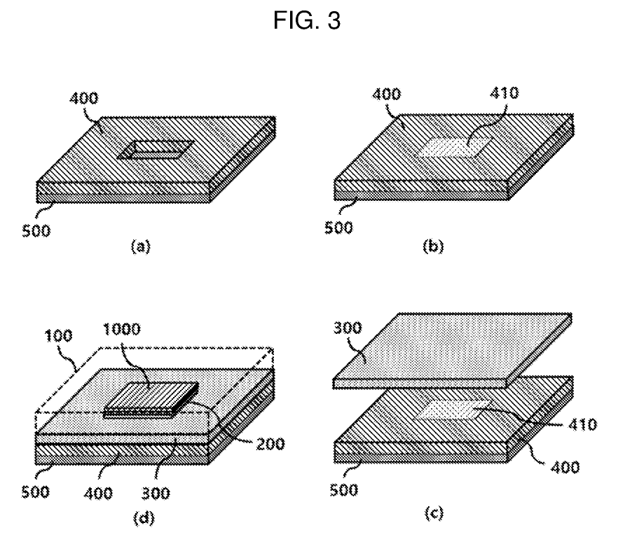

FIGS. 3 to 5 are flowcharts illustrating a method for manufacturing a substrate for a semiconductor device according to an embodiment of the present disclosure.

First, FIG. 3 is a method for manufacturing a substrate for a semiconductor device according to an embodiment of the present disclosure, in which the first bonding layer 400, the second bonding layer 300, and the sintered metal 410 are preform materials.

Referring to FIG. 3A, the first bonding layer 400 is bonded on the heat sink 500, and the first bonding layer 400 may include the sintered groove at the position corresponding to the semiconductor device 1000. The heat sink 500 and the first bonding layer 400 may be bonded by a fixing material. The first bonding layer 400 may be made of a soldering material and may include grease, plastic, ceramic, etc. In addition, the first bonding layer 400 may be a preform type and may be tailored in the sintered groove in the solid form.

Referring to FIG. 3B, in the method for manufacturing a substrate for a semiconductor device, the sintered metal 410 may be bonded to the sintered groove formed in the first bonding layer 400. Like the first bonding layer, the sintered metal 410 may be sintered in the solid form in the preform type to tailor the sintered groove. The sintered metal 410 may include silver, copper, gold, aluminum, etc., as a sintering material. In addition, the first bonding layer 400 is formed through the soldering process, and the sintered metal 410 is formed through the sintering process. In this case, the soldering process may be performed at a higher temperature than the sintering process.

Referring to FIGS. 3C and 3D, in the method for manufacturing a substrate for a semiconductor device, the second bonding layer 300 and the power module 100 including the semiconductor device 1000 may be bonded over the first bonding layer 400 to which the sintered metal 410 is bonded. Similar to the first bonding layer 400, the second bonding layer 300 may be formed in the preform type. In addition, the second bonding layer 300 may be made of a soldering material and may include grease, plastic, ceramic, etc. The semiconductor device 1000 of the power module 100 may be electrically connected to a circuit board formed on the second bonding layer 300 through the soldering. In addition, the semiconductor device 1000 may be disposed at a position corresponding to the sintered metal 410.

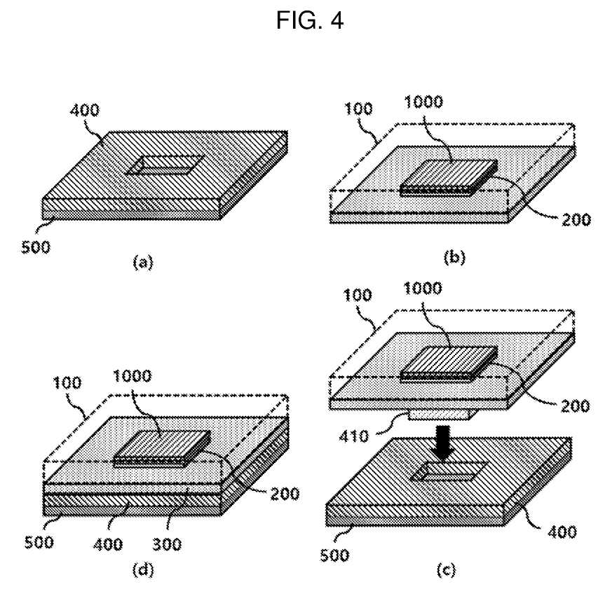

FIG. 4 is a method for manufacturing a substrate for a semiconductor device according to an embodiment of the present disclosure, in which the first bonding layer 400 and the sintered metal 410 are made of a paste material and the second bonding layer 300 is made of a preform material.

Referring to FIG. 4A, in the method for manufacturing a substrate for a semiconductor device, the first bonding layer 400 is bonded on the heat sink 500, and the first bonding layer 400 may include a sintered groove at the position corresponding to the semiconductor device 1000. The heat sink 500 and the first bonding layer 400 may be bonded by a fixing material. The first bonding layer 400 may be made of the soldering material and may include grease, plastic, ceramic, etc. In addition, the first bonding layer 400 can be printed in a paste type with viscosity.

Referring to FIG. 4B, the second bonding layer 300 may be bonded under a semiconductor device 1000 of the power module 100. The second bonding layer 300 and the semiconductor device 1000 may be electrically connected through the solder layer 200.

Referring to FIG. 4C, the method for manufacturing a substrate for a semiconductor device may be such that the sintered metal 410 may be bonded under the second bonding layer 300 at the position corresponding to the position of the semiconductor device 1000. The sintered metal 410 can be printed in a paste type with viscosity. In addition, the sintered metal 410 may include a silver, copper, gold, aluminum, etc.

Referring to FIG. 4D, the method for manufacturing a substrate for a semiconductor device may couple the second bonding layer 300 and the first bonding layer 400 so that the sintered metal 410 is inserted into the sintered groove formed in the first bonding layer 400. In addition, the first bonding layer 400 is formed through the soldering process, and the sintered metal 410 is formed through the sintering process. In this case, the soldering process may be performed at a higher temperature than the sintering process.

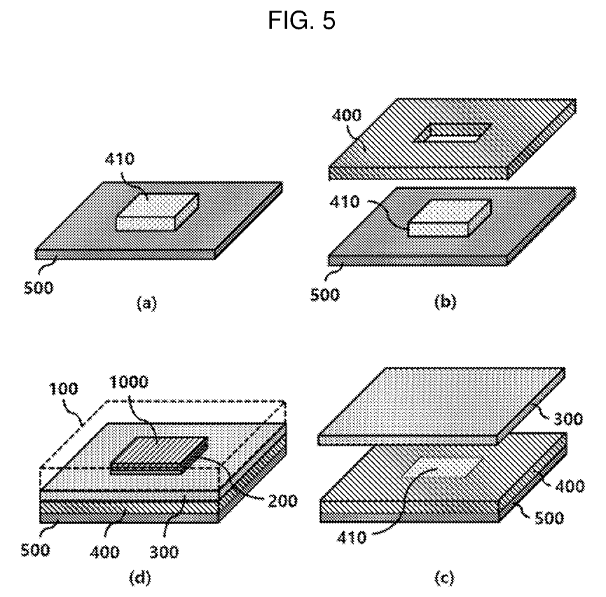

FIG. 5 is a method for manufacturing a substrate for a semiconductor device according to an embodiment of the present disclosure, in which the first bonding layer 400 may be made of a preform material and the sintered metal 410 may be made of a paste material.

Referring to FIG. 5A, the method for manufacturing a substrate for a semiconductor device may print the sintered metal 410 on the heat sink 500 at the position corresponding to the semiconductor device 1000. In this case, the sintered metal 410 can be printed in a paste type with viscosity. In addition, the sintered metal 410 may include a silver, copper, gold, aluminum, etc.

Referring to FIG. 5B, in the method for manufacturing a substrate for a semiconductor device, the first bonding layer 400 with the insertion groove formed may be bonded on the heat sink 500 so that the sintered metal 410 printed on the heat sink 500 may be inserted. The first bonding layer 400 can be printed in the solid form in the preform type. In addition, the first bonding layer 400 may be made of the soldering material and may include grease, plastic, ceramic, etc. In addition, the first bonding layer 400 is formed through the soldering process, and the sintered metal 410 is formed through the sintering process. In this case, the soldering process may be performed at a higher temperature than the sintering process.

Referring to FIGS. 5C and 5D, in the method for manufacturing a substrate for a semiconductor device, the second bonding layer 300 including the circuit board and the power module 100 including the semiconductor device 1000 may be bonded over a first bonding layer 400. Similar to the first bonding layer 400, the second bonding layer 300 may be formed in the preform type. In addition, the second bonding layer 300 may be made of a soldering material and may include grease, plastic, ceramic, etc. The semiconductor device 1000 of the power module 100 may be electrically connected to the circuit board formed on the second bonding layer 300 through the solder layer 200. In addition, the semiconductor device 1000 may be disposed at the position corresponding to the sintered metal 410.

According to the present disclosure, it is possible to more efficiently release the heat generated from the semiconductor device of the power module.

In addition, according to the present disclosure, it is possible to minimize the content of the sintering material to reduce the manufacturing cost.

Although preferred embodiments of the present disclosure have been described above, the embodiments disclosed in the present disclosure are only for explaining, not limiting, the technical spirit of the present disclosure. Therefore, the technical idea of the present disclosure includes not only each disclosed embodiment but also a combination of the disclosed embodiments, and furthermore, the scope of the technical idea of the present disclosure is not limited by these embodiments. In addition, many modifications and alterations of the present disclosure may be made by those skilled in the art to which the present disclosure pertains without departing from the spirit and scope of the accompanying claims. In addition, it is to be considered that all of these modifications and alterations fall within the scope of the present disclosure.

What is claimed is:

1. A method for manufacturing a substrate for a semiconductor device for dissipating heat generated from a semiconductor device, the method comprising:
(a) bonding a first bonding layer comprising a sintered groove at a position corresponding to the semiconductor device on a heat sink;
(b) inserting a sintered metal into the sintered groove;
(c) bonding a second bonding layer comprising a circuit board on the first bonding layer; and
(d) bonding the semiconductor device on the second bonding layer,
wherein at least one of the first bonding layer, the second bonding layer, and the sintered metal comprises a preform material.

2. The method of claim 1, wherein the sintered metal is selected from the group consisting of silver, copper, gold, and aluminum.

3. The method of claim 1, wherein at least one of the first bonding layer and the second bonding layer comprises a solder material.

4. The method of claim 1, wherein the sintered metal is bonded through a sintering process, and
wherein the first and second bonding layers are bonded through a soldering process.

5. A method for manufacturing a substrate for a semiconductor device for dissipating heat generated from a semiconductor device, the method comprising:
(a) bonding a first bonding layer comprising a sintered groove at a position corresponding to the semiconductor device on a heat sink;
(b) bonding a second bonding layer comprising a circuit board under the semiconductor device;
(c) bonding a sintered metal at a position corresponding to a position of the semiconductor device under the second bonding layer; and
(d) bonding the second bonding layer and the first bonding layer so that the sintered metal is inserted into the sintered groove of the first bonding layer,
wherein at least one of the first bonding layer and the sintered metal comprises a paste material.

6. The method of claim 5, wherein the sintered metal is selected from the group consisting of silver, copper, gold, and aluminum.

7. The method of claim 5, wherein at least one of the first bonding layer and the second bonding layer comprises a solder material.

8. The method of claim 5, wherein the sintered metal is bonded through a sintering process, and
wherein the first and second bonding layers are bonded through a soldering process.

9. A method for manufacturing a substrate for a semiconductor device for dissipating heat generated from a semiconductor device, the method comprising:
(a) printing a sintered metal on a heat sink at a position corresponding to the semiconductor device;
(b) bonding a first bonding layer comprising a sintered groove into which the sintered metal is inserted on the heat sink so that the sintered metal is inserted into the sintered groove;
(c) bonding a second bonding layer comprising a circuit board on the first bonding layer; and
(d) bonding the semiconductor device on the second bonding layer,
wherein the first bonding layer comprises a preform material, and
wherein the sintered metal comprises a paste material.

10. The method of claim 9, wherein the sintered metal is selected from the group consisting of silver, copper, gold, and aluminum.

11. The method of claim 9, wherein at least one of the first bonding layer and the second bonding layer comprises a solder material.

12. The method of claim 11, wherein at least one of the first and second bonding layers comprises a material selected from the group consisting of grease, plastic, and ceramic.

13. The method of claim 9, wherein the sintered metal is bonded through a sintering process, and
wherein the first and second bonding layers are bonded through a soldering process.

14. The method of claim 13, wherein the soldering process is performed at a higher temperature than the sintering process.

15. A substrate for a semiconductor device for dissipating heat generated from a semiconductor device, the substrate comprising:
a second bonding layer bonded under the semiconductor device to form a circuit board;
a first bonding layer bonded under the second bonding layer and having a sintered groove formed at a position corresponding to the semiconductor device; and
a heat sink bonded under the first bonding layer,
wherein a sintered metal is bonded to the sintered groove of the first bonding layer.

16. The substrate of claim 15, wherein the sintered metal is selected from the group consisting of silver, copper, gold, and aluminum.
